(19) United States
(12) Patent Application Publication
(10) Pub. No.: US 2023/0125822 A1
(43) Pub. Date: Apr. 27, 2023

(54) IMMERSION COOLING FOR INTEGRATED CIRCUIT DEVICES

(71) Applicant: Intel Corporation, Santa Clara, CA (US)

(72) Inventors: Abdulafeez Adebiyi, Chandler, AZ (US); Je-Young Chang, Tempe, AZ (US); Devdatta Kulkarni, Portland, OR (US)

(73) Assignee: Intel Corporation, Santa Clara, CA (US)

(21) Appl. No.: 17/512,138

(22) Filed: Oct. 27, 2021

(51) Int. Cl. H01L 23/44; H01L 23/373

(52) U.S. Cl. CPC H01L 23/445; H01L 23/3737

(57) ABSTRACT

A two-phase immersion cooling system for integrated circuit assembly may be formed utilizing a heat dissipation device thermally coupled to at least one integrated circuit device, wherein the heat dissipation device may include a surface enhancement structure and a boiling enhancement material layer, such as a micro-porous material, on the surface enhancement structure.

### TECHNICAL FIELD

Embodiments of the present description generally relate to the field of thermal management for integrated circuit devices, and, more specifically, to immersion cooling for integrated circuit devices.

### BACKGROUND

The integrated circuit industry is continually striving to produce ever faster, smaller, and thinner integrated circuit devices and packages for use in various electronic products, including, but not limited to, computer servers and portable products, such as portable computers, electronic tablets, cellular phones, digital cameras, and the like.

As these goals are achieved, the integrated circuit devices become smaller. Accordingly, the density of power consumption of electronic components within the integrated circuit devices has increased, which, in turn, increases the average junction temperature of the integrated circuit device. If the temperature of the integrated circuit device becomes too high, the integrated circuits may be damaged or destroyed. Thus, heat dissipation devices are used to remove heat from the integrated circuit devices in an integrated circuit package. In one example, heat spreading and dissipation devices may be thermally attached to integrated circuit devices for heat removal. The heat spreading and dissipation devices, in turn, dissipate the heat into the surrounding atmosphere. In another example, a liquid cooling device, such as a heat exchanger or a heat pipe, may be thermally attached to integrated circuit devices for heat removal. However, as power densities and power envelopes increase to reach peak performance, these methods are becoming ineffective in removing sufficient heat.

One emerging heat removal technique is two-phase immersion cooling. This technique essentially comprises immersing an integrated circuit assembly into a liquid cooling bath containing a low boiling point liquid which vaporizes and, thus, cooling the integrated circuit assembly through latent heat transfer, as it generates heat. Although it is a promising technology, two-phase immersion cooling has various challenges to effective operation, as will be understood to those skilled in the art.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an integrated circuit assembly, according to one embodiment of the present description.

FIGS. 2-4 are side cross-sectional and oblique views of an integrated circuit package having a surface area enhancement structure formed on a heat dissipation device and a boiling enhancement material layer formed on the surface area enhancement structure, according to an embodiment of the present description.

FIGS. 5-7 are side cross-sectional and oblique views of an integrated circuit package having a surface area enhancement structure formed in a heat dissipation device and a boiling enhancement material layer formed on the surface area enhancement structure, according to another embodiment of the present description.

FIG. 8 is a side cross-sectional view of an integrated circuit package having a surface area enhancement structure formed through a heat dissipation device and a boiling enhancement material layer formed on the surface area enhancement structure, according to a further embodiment of the present description.

FIG. 9 is a side cross-sectional view of an integrated circuit package having a variable pitch surface area enhancement structure formed in a heat dissipation device and a boiling enhancement material layer formed on the surface area enhancement structure, according to still a further embodiment of the present description.

FIG. 10 is an electronic system, according to one embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures, as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description relate to the use of two-phase immersion cooling for integrated circuit assemblies. In one embodiment of the present description, an integrated circuit assembly may comprise an integrated circuit package having a heat dissipation device thermally coupled to at least one integrated circuit device, wherein the heat dissipation device includes a surface enhancement structure and a boiling enhancement material layer on the surface enhancement structure.

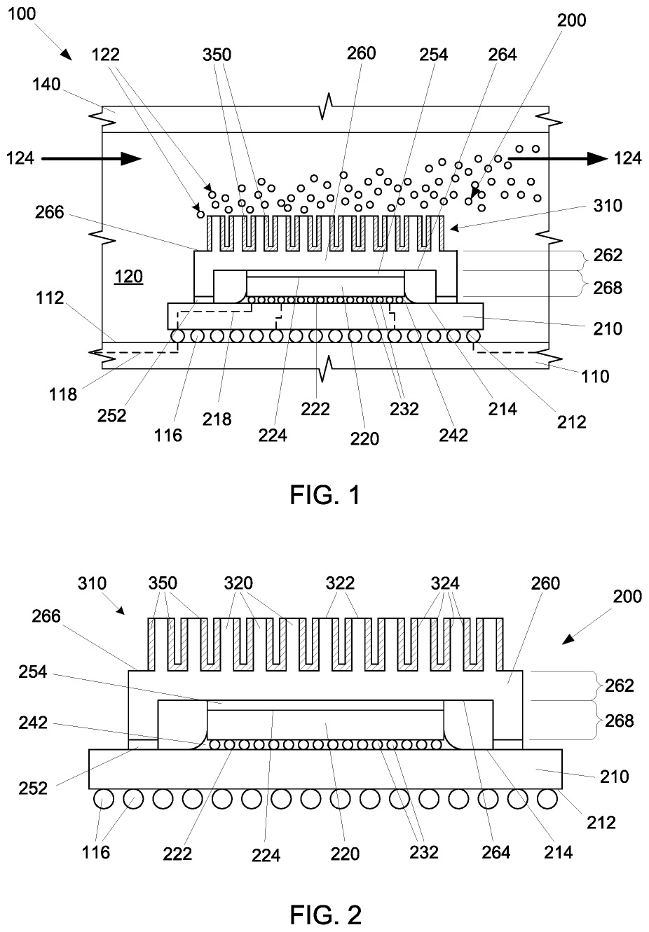

FIG. 1 illustrates an integrated circuit assembly 100 having at least one integrated circuit package 200 electrically attached to an electronic substrate 110. The electronic substrate 110 may be any appropriate structure, including, but not limited to, a motherboard, printed circuit board, and the like. The electronic substrate 110 may comprise a plurality of dielectric material layers (not shown), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like.

The electronic substrate 110 may further include conductive routes 118 or “metallization” (shown in dashed lines) extending through the electronic substrate 110. As will be understood to those skilled in the art, the conductive routes 118 may be a combination of conductive traces (not shown) and conductive vias (not shown) extending through the plurality of dielectric material layers (not shown). These conductive traces and conductive vias are well known in the art and are not shown in FIG. 1 for purposes of clarity. The conductive traces and the conductive vias may be made of any appropriate conductive material, including but not limited to, metals, such as copper, silver, nickel, gold, and aluminum, alloys thereof, and the like. As will be understood to those skilled in the art, the electronic substrate 110 may be a cored substrate or a coreless substrate.

The at least one integrated circuit package 200 may be electrically attached to the electronic substrate 110 in a configuration generally known as a flip-chip or controlled collapse chip connection (“C4”) configuration, according to an embodiment of the present description. The integrated circuit package 200 may comprise a package substrate or interposer 210 with a first surface 212 and an opposing second surface 214, and an integrated circuit device 220 electrically attached proximate the second surface 214 of the package interposer 210. In an embodiment of the present description, the package interposer 210 may be attached to the electronic substrate or board 110 with a plurality of package-to-substrate interconnects 116. In one embodiment of the present description, the package-to-substrate interconnects 116 may extend between bond pads (not shown) proximate a first surface 112 of the electronic substrate 110 and bond pads (not shown) proximate the first surface 212 of the package interposer 210.

The package interposer 210 may comprise any of the materials and/or structures as discussed previously with regard to the electronic substrate 110. The package interposer 210 may further include conductive routes 218 or “metallization” (shown in dashed lines) extending through the package interposer 210, which may comprise any of the materials and/or structures as discussed previously with regard to the conductive routes 118 of the electronic substrate 110. Bond pads (not shown) proximate the first surface 212 of the package interposer 210 may be in electrical contact with the conductive routes 218, and the conductive routes 218 may extend through the package interposer 210 and be electrically connected to bond pads (not shown) proximate the second surface 214 of the package substrate 210. As will be understood to those skilled in the art, the package interposer 210 may be a cored substrate or a coreless substrate.

The integrated circuit device 220 may be any appropriate device, including, but not limited to, a microprocessor, a chipset, a graphics device, a wireless device, a memory device, an application specific integrated circuit, a transceiver device, an input/output device, combinations thereof, stacks thereof, and the like. As shown in FIG. 1, the integrated circuit device 220 may have a first surface 222 and an opposing second surface 224. It is understood that, although only a single integrated circuit device 220 is illustrated, any appropriate number of integrated circuit devices may be electrically attached to the package interposer 210.

In an embodiment of the present description, the integrated circuit device 220 may be electrically attached to the package interposer 210 with a plurality of device-to-substrate interconnects 232. In one embodiment of the present description, the device-to-substrate interconnects 232 may extend between bond pads (not shown) on the second surface 214 of the package interposer 210 and bond pads (not shown) on the first surface 222 of the integrated circuit device 220. The device-to-substrate interconnects 232 may be any appropriate electrically conductive material or structure, including, but not limited to, solder balls, metal bumps or pillars, metal filled epoxies, or a combination thereof. In one embodiment of the present description, the device-to-substrate interconnects 232 may be solder balls formed from tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys). In another embodiment of the present description, the device-to-substrate interconnects 232 may be copper bumps or pillars. In a further embodiment of the present description, the device-to-substrate interconnects 232 may be metal bumps or pillars coated with a solder material.

The device-to-substrate interconnects 232 may be in electrical communication with integrated circuitry (not shown) within the integrated circuit device 220 and may be in electrical contact with the conductive routes 218. The conductive routes 218 may extend through the package interposer 210 and be electrically connected to package-to-board interconnects 116. As will be understood to those skilled in the art, the package interposer 210 may reroute a fine pitch (center-to-center distance) of the device-to-interposer interconnects 232 to a relatively wider pitch of the package-to-substrate interconnects 116. The package-to-substrate interconnects 116 may be any appropriate electrically conductive material, including, but not limited to, metal filled epoxies and solders, such as tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys). Although FIG. 1 shows the integrated circuit package 200 attached to the electronic substrate 110 with an interconnect-type attachment, the embodiments of the present description are not so limited. For example, the integrated circuit package 200 may be attached to a socket (not shown) that is electrically attached to the first surface 112 of the electronic substrate 110.

As further shown in FIG. 1, the integrated circuit package 200 may further include a heat dissipation device 260, such as an integrated heat spreader, that may be thermally coupled with the second surface 224 of the integrated circuit device 220 with a thermal interface material 254. The heat dissipation device 260 may comprise a main body 262, having a first surface 264 and an opposing second surface 266, and at least one boundary wall 268 extending from the first surface 264 of the main body 262 of the heat dissipation device 260. The at least one boundary wall 268 may be attached or sealed to the first surface 212 of the package interposer 210 with an attachment adhesive or sealant layer 252.

The heat dissipation device 260 may be made of any appropriate thermally conductive material, including, but not limited to, at least one metal material and alloys of more than one metal, or highly doped glass or highly conductive ceramic material, such as aluminum nitride. In an embodiment of the present description, the heat dissipation device 260 may comprise copper, nickel, aluminum, alloys thereof, laminated metals including coated materials (such as nickel coated copper), and the like. The thermal interface material 254 may be any appropriate, thermally conductive material, including, but not limited to, a thermal grease, a thermal gap pad, a polymer, an epoxy filled with high thermal conductivity fillers, such as metal particles or silicon particles, a metal alloy, such as a solder material and a liquid metal, and the like.

As illustrated in FIG. 1, the heat dissipation device 260 may be a single material throughout, such as when the heat dissipation device 260, including the heat dissipation device boundary wall 268, is formed by a single process step, including but not limited to, stamping, skiving, molding, and the like. However, embodiments of the present description may also include the heat dissipation device 260 being made of more than one component. For example, the heat dissipation device boundary wall 268 may be formed separately from the main body 262, then attached together to form the heat dissipation device 260. In one embodiment of the present description, the boundary wall 268 may be a single “picture frame” structure surrounding the integrated circuit device 220.

The attachment adhesive 252 may be any appropriate material, including, but not limited to, silicones (such as polydimethylsiloxane), epoxies, and the like. It is understood that the boundary wall 268 not only secures the heat dissipation device 260 to the package interposer 210, but also helps to maintain a desired distance (e.g. bond line thickness) between the first surface 264 of the heat dissipation device 260 and the second surface 224 of the integrated circuit device 220.

Prior to the attachment of the heat dissipation device 260, an electrically-insulating underfill material 242 may be disposed between the integrated circuit device 220 and the package interposer 210, which substantially encapsulates the device-to-interposer interconnects 232. The underfill material 242 may be used to reduce mechanical stress issues that can arise from thermal expansion mismatch between the package interposer 210 and the integrated circuit device 220. The underfill material 242 may be an appropriate material, including, but not limited to epoxy, cyanoester, silicone, siloxane and phenolic based resins, that has sufficiently low viscosity to be wicked between the integrated circuit device 220 and the package interposer 210 by capillary action when introduced by an underfill material dispenser (not shown), which will be understood to those skilled in the art. The underfill material 242 may be subsequently cured (hardened), such as by heat or radiation.

As shown in FIG. 1, the integrated circuit assembly 100 may further include a dielectric low-boiling point liquid 120 in contact with the integrated circuit package 200. As illustrated, the dielectric low-boiling point liquid 120 may vaporize (shown in vapor or gas state as bubbles 122) on the heat dissipation device 260. For the purpose of the present application, the dielectric low-boiling point liquid 120 may be defined to be a liquid having a boiling point lower than about 60 degrees Celsius. In one embodiment of the present description, the dielectric low-boiling point liquid 120 may comprise a fluorocarbon-based fluid. In an embodiment of the present description, the dielectric low-boiling point liquid 120 may comprise fluorochemicals, including, but not limited to perfluorohexane, perfluorocarbon, perfluoroketone, hydrofluoroether (HFE), hydrofluorocarbon (HFC), hydrofluoroolefin (HFO), and the like. In another embodiment of the present description, the dielectric low-boiling point liquid 120 may comprise a perfluoroalkylmorpholine, such as 2,2,3,3,5,5,6,6-octafluoro-4-(trifluoromethyl)morpholine. As further shown in FIG. 1, the dielectric low-boiling point liquid 120 may flow (shown by arrows 124) between the electronic substrate 110 and an adjacent electronic substrate or fluid containment structure 140.

In the embodiments of the present description, at least one surface area enhancement structure 310 may be formed on the second surface 266 of the main body 262 of the heat dissipation device 260 or extend into the main body 262 of the heat dissipation device 260 from the second surface 266 thereof, and at least one boiling enhancement material layer 350 formed on at least a portion of the at least one surface area enhancement structure 310. Such configurations, the at least one surface area enhancement structure 310 results in greater surface area for the at least one boiling enhancement material layer 350 to contact the dielectric low-boiling point liquid 120 in a liquid state to nucleate and form the vapor or gas state 122. It is understood that having the dielectric low-boiling point liquid 120 close to the heat source (e.g., the integrated circuit device 220) and maximizing the contact area between the dielectric low-boiling point liquid 120 and heat dissipation device 260 may increase heat dissipation efficiency.

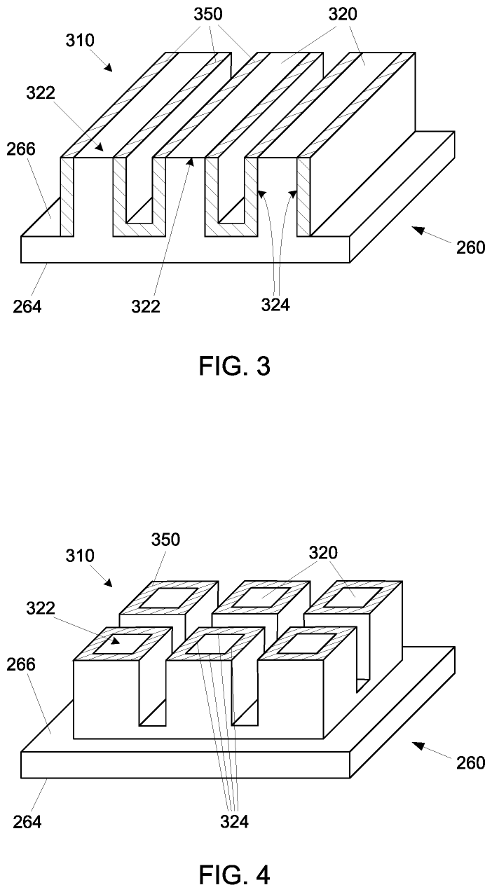

As shown in FIG. 2, in one embodiment of the present description, the surface area enhancement structure 310 may comprise at least one projection 320 extending from the second surface 266 of the heat dissipation device 260. As shown, the at least one projection 320 may be defined by at least one sidewall 324 and a top surface 322. By way of example, the projections 320 may be positioned with a pitch of between about 0.8 and 5 mm.

In one embodiment of the present description, the at least one boiling enhancement material layer 350 may be formed on the at least one projection 320. In a specific embodiment, as shown in FIG. 2, the at least one boiling enhancement material layer 350 may contact the at least one sidewall 324 of the at least one projection 320 without contacting the top surface 322 of the at least one projection 320. Such a configuration may allow for greater than 50% contact area with a thermal tool (not shown), which is typically required for product validation, as will be understood to those skilled in the art. Furthermore, as shown, the boiling enhancement material layer 350 may contact the second surface 266 of the heat dissipation device 260.

The at least one projection 320 may have any appropriate shape and/or configuration. In one embodiment of the present description, as shown in FIG. 3, the at least one projection 320 may be a plurality of fins or wall-shaped structures. In another embodiment of the present description, as shown in FIG. 4, the at least one projection 320 may be a plurality of pillar or column shaped structures. In one embodiment of the present description, the at least one projection 320 may be made by removing a portion of the main body 262 of the heat dissipation device 260 by any appropriate process known in the art, including, but not limited to, machining, etching, ablating, and the like, or by an additive process, including, but not limited to, a 3D build-up process or the like, after the fabrication of the heat dissipation device 260. In another embodiment of the present description, the at least one projection 320 may be formed during the fabrication of the heat dissipation device 260, such as in a stamping or molding process.

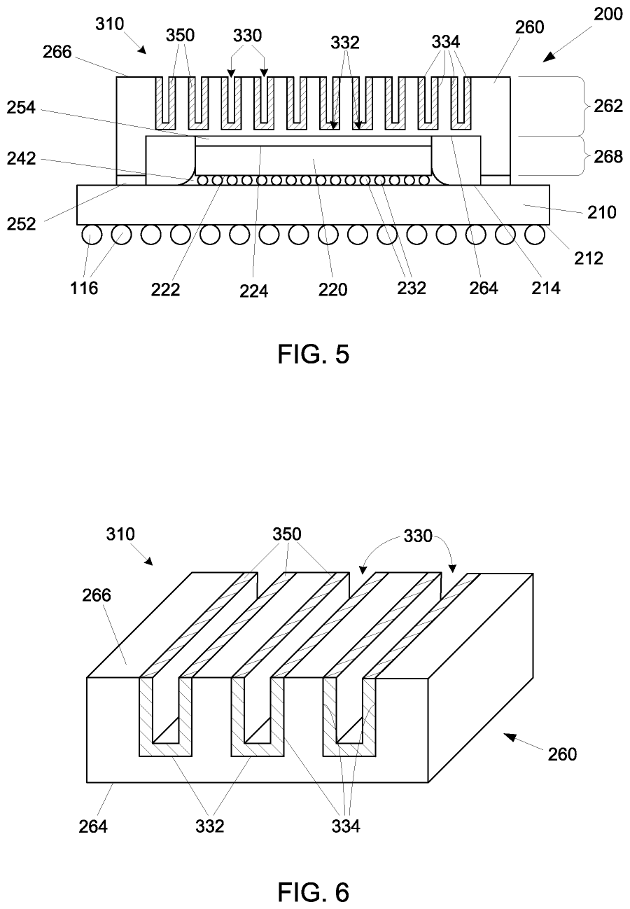

As shown in FIG. 5, in an embodiment of the present description, the surface area enhancement structure 310 may comprise at least one opening 330 extending into the heat dissipation device 260 from the second surface 266 thereof. As shown, the at least one opening 330 may be defined by at least one sidewall 334 and a bottom surface 332. By way of example, the openings 330 may been positioned with a pitch of between about 0.8 and 5 mm.

In one embodiment of the present description, the at least one boiling enhancement material layer 350 may be formed in the at least one opening 330. In a specific embodiment, as shown in FIG. 5, the at least one boiling enhancement material layer 350 may contact the at least one sidewall 334 and the bottom surface 332 of the at least one opening 330 without contacting the second surface 266 of the heat dissipation device 266. As with the embodiments described in FIGS. 2-4, such a configuration may allow for greater than 50% contact area with a thermal tool (not shown), which is typically required for product validation, as will be understood to those skilled in the art.

The at least one opening 330 may have any appropriate shape and/or configuration. In one embodiment of the present description, as shown in FIG. 6, the at least one opening 330 may be a plurality of slots or trenches. In another embodiment of the present description, as shown in FIG. 7, the at least one opening 320 may be a plurality of circular holes. The at least one opening 330 may be made by any appropriate process known in the art, including, but not limited to, machining, etching, ablating, drilling, and the like, after the fabrication of the heat dissipation device 260, or may be formed during the fabrication of heat dissipation device 260, such as by a stamping or molding process.

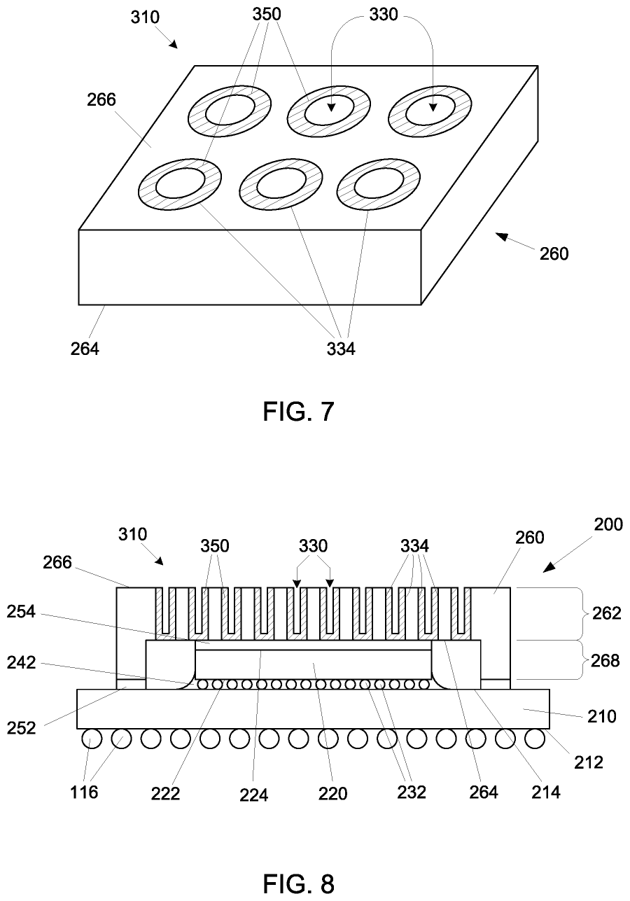

In a further embodiment of the present description, as shown in FIG. 8, the at least one opening 330 may extend through the heat dissipation device 260 from the first surface 264 to the second surface 266 of the main body 262. This will allow at least one opening 330 to contact the thermal interface material 254, which eliminates any thermal resistance from the heat dissipation device 260.

In one embodiment of the present description, the boiling enhancement material layer 350 may be a micro-porous coating. As will be understood to those skilled in the art, a micro-porous coating may provide capillarity for fluid travel of the dielectric low-boiling point liquid 120 (see FIG. 1) and provide better nucleation sites. In an embodiment of the present description, the boiling enhancement material layer 350 may comprise conductive particles dispersed in an epoxy material. In a specific embodiment of the present description, the boiling enhancement material layer 350 comprises a mixture of conductive particles, epoxy, and methylethylketone. In another specific embodiment of the present description, the conductive particles may comprise alumina particles. In still another specific embodiment of the present description, the conductive particles may comprise diamond particles. In one embodiment of the present description, the conductive particles may have an average diameter between about 1 and 20 microns. In a specific embodiment of the present description, the conductive particles may have an average diameter of about 10 microns. The boiling enhancement material layer 350 may be formed by any appropriate process known in the art, including, but not limited to, spray coating. In one embodiment, the boiling enhancement material layer 350 may be substantially conformal. Additionally, a hydrophilic coating (not shown) may be layered on the micro-porous coating to further improved nucleate boiling performance, as known in the art. In another embodiment of the present description, the boiling enhancement material layer 350 may comprise dispersed metal particles which is manufactured by sintering process, or build up process, including, but not limited to, cold spray, plating process, and the like. In a specific embodiment of the present description, the metal particles may comprise copper, aluminum, and the like.

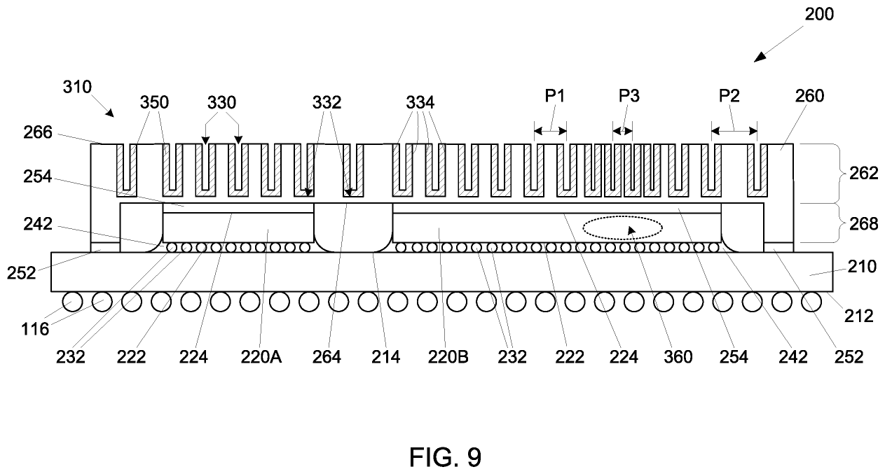

Although only one integrated circuit device 220 is illustrated in FIGS. 1, 2, 5, and 8, it is understood that any appropriate number of integrated circuit devices may be mounted on the package interposer 210. For example, in FIG. 9, two integrated circuit devices 220A and 220B are illustrated with a shared heat dissipation device 260. As further shown in FIG. 9, the projections 320 (not shown) and/or openings 330 may have variable pitches which allows for a greater concentration of boiling enhancement material where it is needed and a lesser concentration where it is less needed, comparatively. As illustrated, the openings 330 may have a medium first pitch P1 in areas over the integrated circuit devices 220A, 220B, and a wider pitch second pitch P2 in areas that are outside of the location of the integrated circuit device 220A, 220B. Furthermore, at least one of the integrated circuit devices (illustrated as element 220B) may have at least one “hotspot” 360 (area of very high heat generation). In such hotspot locations, a tight third pitch P3 (i.e., a pitch less than first pitch P1 and second pitch P2) may be implemented to concentrate the boiling enhancement material layer 350 over the hotspot 360 for concentrated heat removal, as will be understood to those skilled in the art.

Although the embodiments of the present description are primarily directed to immersive cooling, it is understood that the embodiments are not so limited. Where appropriate, the embodiments of the present description may be incorporated into various heat dissipation assemblies.

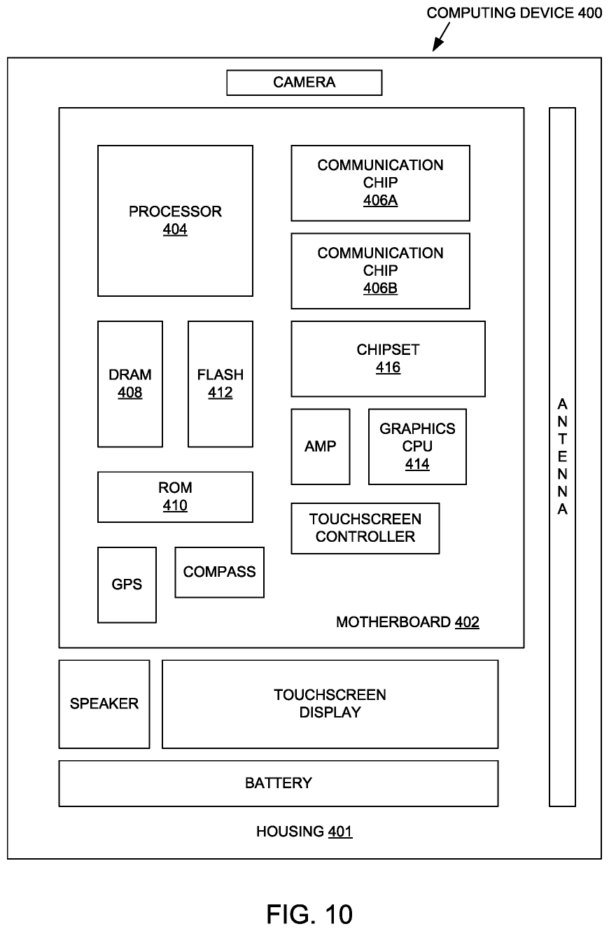

FIG. 10 illustrates an electronic or computing device/system 400 in accordance with one implementation of the present description. The computing device 400 may include a housing 401 having a board 402 disposed therein. The computing device 400 may include a number of integrated circuit components, including but not limited to a processor 404, at least one communication chip 406A, 406B, volatile memory 408 (e.g., DRAM), non-volatile memory 410 (e.g., ROM), flash memory 412, a graphics processor or CPU 414, a digital signal processor (not shown), a crypto processor (not shown), a chipset 416, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 402. In some implementations, at least one of the integrated circuit components may be a part of the processor 404.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

The entire computing device 400 or at least one of the integrated circuit components within the computing device 400 may be immersed in a two-phase immersion system. In one embodiment, the integrated circuit component may comprise an integrated circuit package having a heat dissipation device thermally coupled to integrated circuit device, wherein the heat dissipation device includes at least one surface area enhancement structure and includes at least one boiling enhancement layer formed on or directly attached to the at least one surface area enhancement structure.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-10. The subject matter may be applied to other integrated circuit devices and assembly applications, as well as any appropriate electronic application, as will be understood to those skilled in the art.

The following examples pertain to further embodiments and specifics in the examples may be used anywhere in one or more embodiments, wherein Example 1 is an apparatus, comprising a heat dissipation device including at least one surface area enhancement structure formed therein and/or thereon, and at least one boiling enhancement material layer on at least a portion of the surface area enhancement structure of the heat dissipation device.

In Example 2, the subject matter of Example 1 can optionally include the heat dissipation device having a first surface and a second surface and wherein the at least one surface area enhancement structure comprises at least one projection extending from the second surface of the heat dissipation device.

In Example 3, the subject matter of Example 2 can optionally include the at least one projection being defined by at least one sidewall and a top surface.

In Example 4, the subject matter of Example 3 can optionally include the at least one boiling enhancement material layer contacting the at least one sidewall of the at least one projection without contacting the top surface of the at least one projection.

In Example 5, the subject matter of Example 4 can optionally include the at least one boiling enhancement material layer contacting the second surface of the heat dissipation device.

In Example 6, the subject matter of Example 1 can optionally include the heat dissipation device having a first surface and an opposing second surface, wherein the at least one surface area enhancement structure comprises at least one opening extending into the heat dissipation device from the second surface thereof.

In Example 7, the subject matter of Example 6 can optionally include the at least one opening being defined by at least one sidewall and a bottom surface, and wherein the at least one boiling enhancement material layer contacts the at least one sidewall and the bottom surface of the at least one opening.

In Example 8, the subject matter of Example 7 can optionally include the at least one boiling enhancement material layer contacting the at least one sidewall and the bottom surface of the at least one opening without contacting the second surface of the heat dissipation device.

In Example 9, the subject matter of Example 6 can optionally include the at least one surface area enhancement structure comprising at least one opening extending through the heat dissipation device from the first surface to the second surface thereof.

In Example 10, the subject matter of any of Examples 1 to 9 can optionally include the at least one boiling enhancement material layer comprising a micro-porous coating.

In Example 11, the subject matter of Example 10 can optionally include the micro-porous coating comprising conductive particles dispersed in an epoxy material.

In Example 12, the subject matter of Example 10 can optionally include the micro-porous coating comprising a mixture of conductive particles, epoxy material, and methylethylketone.

In Example 13, the subject matter of any of Examples 11 to 12 can optionally include the conductive particles comprising at least one of alumina particles and diamond particles.

In Example 14, the subject matter of Example 10 can optionally include the micro-porous coating comprising dispersed metal particles.

In Example 15, the subject matter of any of Examples 1 to 14 can optionally include a dielectric low-boiling point liquid contacting the boiling enhancement material layer.

Example 16 is an apparatus, comprising an integrated circuit device having a first surface and an opposing second surface, a heat dissipation device having a first surface and an opposing second surface, wherein the first surface of the first surface of the heat dissipation device is thermally attached to the second surface of the integrated circuit device and wherein the heat dissipation device includes at least one surface area enhancement structure formed therein and/or thereon, and at least one boiling enhancement material layer on at least a portion of the surface area enhancement structure of the heat dissipation device.

In Example 17, the subject matter of Example 16 can optionally include the at least one surface area enhancement structure comprising at least one projection extending from the second surface of the heat dissipation device.

In Example 18, the subject matter of Example 17 can optionally include the at least one projection being defined by at least one sidewall and a top surface.

In Example 19, the subject matter of Example 18 can optionally include the at least one boiling enhancement material layer contacting the at least one sidewall of the at least one projection without contacting the top surface of the at least one projection.

In Example 20, the subject matter of Example 19 can optionally include the at least one boiling enhancement material layer contacting the second surface of the heat dissipation device.

In Example 21, the subject matter of Example 16 can optionally include the at least one surface area enhancement structure comprising at least one opening extending into the heat dissipation device from the second surface thereof.

In Example 22, the subject matter of Example 21 can optionally include the at least one opening being defined by at least one sidewall and a bottom surface, and wherein the at least one boiling enhancement material layer contacts the at least one sidewall and the bottom surface of the at least one opening.

In Example 23, the subject matter of Example 22 can optionally include the at least one boiling enhancement material layer contacting the at least one sidewall and the bottom surface of the at least one opening without contacting the second surface of the heat dissipation device.

In Example 24, the subject matter of Example 21 can optionally include the at least one surface area enhancement structure comprising at least one opening extending through the heat dissipation device from the first surface to the second surface thereof.

In Example 25, the subject matter of any of Examples 16 to 24 can optionally include the at least one boiling enhancement material layer comprising a micro-porous coating.

In Example 26, the subject matter of Example 25 can optionally include the micro-porous coating comprising conductive particles dispersed in an epoxy material.

In Example 27, the subject matter of Example 25 can optionally include the micro-porous coating comprising a mixture of conductive particles, epoxy material, and methylethylketone.

In Example 28, the subject matter of any of Examples 26 to 27 can optionally include the conductive particles comprising at least one of alumina particles and diamond particles.

In Example 29, the subject matter of Example 25 can optionally include the micro-porous coating comprising dispersed metal particles.

In Example 30, the subject matter of any of Examples 16 to 29 can optionally include a dielectric low-boiling point liquid contacting the boiling enhancement material layer.

Example 31 is a system, comprising an electronic board and an integrated circuit package electrically attached to the electronic board, wherein the integrated circuit package comprises an integrated circuit device having a first surface and an opposing second surface, a heat dissipation device having a first surface and an opposing second surface, wherein the first surface of the heat dissipation device is thermally attached to the second surface of the integrated circuit device and wherein the heat dissipation device includes at least one surface area enhancement structure formed therein and/or thereon, and at least one boiling enhancement material layer on at least a portion of the surface area enhancement structure of the heat dissipation device.

In Example 32, the subject matter of Example 31 can optionally include the at least one surface area enhancement structure comprising at least one projection extending from the second surface of the heat dissipation device.

In Example 33, the subject matter of Example 32 can optionally include the at least one projection being defined by at least one sidewall and a top surface.

In Example 34, the subject matter of Example 33 can optionally include the at least one boiling enhancement material layer contacting the at least one sidewall of the at least one projection without contacting the top surface of the at least one projection.

In Example 35, the subject matter of Example 34 can optionally include the at least one boiling enhancement material layer contacting the second surface of the heat dissipation device.

In Example 36, the subject matter of Example 31 can optionally include the at least one surface area enhancement structure comprising at least one opening extending into the heat dissipation device from the second surface thereof.

In Example 37, the subject matter of Example 36 can optionally include the at least one opening being defined by at least one sidewall and a bottom surface, and wherein the at least one boiling enhancement material layer contacts the at least one sidewall and the bottom surface of the at least one opening.

In Example 38, the subject matter of Example 37 can optionally include the at least one boiling enhancement material layer contacting the at least one sidewall and the bottom surface of the at least one opening without contacting the second surface of the heat dissipation device.

In Example 39, the subject matter of Example 36 can optionally include the at least one surface area enhancement structure comprising at least one opening extending through the heat dissipation device from the first surface to the second surface thereof.

In Example 40, the subject matter of any of Examples 31 to 39 can optionally include the at least one boiling enhancement material layer comprising a micro-porous coating.

In Example 41, the subject matter of Example 40 can optionally include the micro-porous coating comprising conductive particles dispersed in an epoxy material.

In Example 42, the subject matter of Example 40 can optionally include the micro-porous coating comprising a mixture of conductive particles, epoxy material, and methylethylketone.

In Example 43, the subject matter of any of Examples 41 to 42 can optionally include the conductive particles comprising at least one of alumina particles and diamond particles.

In Example 44, the subject matter of Example 40 can optionally include the micro-porous coating comprising dispersed metal particles.

In Example 45, the subject matter of any of Examples 31 to 44 can optionally include a dielectric low-boiling point liquid contacting the boiling enhancement material layer.

Having thus described, in detail, embodiments of the present invention, it is understood that the invention defined by the appended claims is not to be limited by particular details set forth in the above description, as many apparent variations thereof are possible without departing from the spirit or scope thereof.

What is claimed is:

1. An apparatus, comprising:
a heat dissipation device including at least one surface area enhancement structure formed therein and/or thereon; and
at least one boiling enhancement material layer on at least a portion of the at least one surface area enhancement structure of the heat dissipation device.

2. The apparatus of claim 1, wherein the heat dissipation device includes a first surface and an opposing second surface and wherein the at least one surface area enhancement structure comprises at least one projection extending from the second surface of the heat dissipation device.

3. The apparatus of claim 2, wherein the at least one projection is defined by at least one sidewall and a top surface.

4. The apparatus of claim 3, wherein the at least one boiling enhancement material layer contacts the at least one sidewall of the at least one projection without contacting the top surface of the at least one projection.

5. The apparatus of claim 4, wherein the at least one boiling enhancement material layer contacts the second surface of the heat dissipation device.

6. The apparatus of claim 1, wherein the heat dissipation device includes a first surface and an opposing second surface and wherein the at least one surface area enhancement structure comprises at least one opening extending into the heat dissipation device from the second surface thereof.

7. The apparatus of claim 6, wherein the at least one opening is defined by at least one sidewall and a bottom surface, and wherein the at least one boiling enhancement material layer contacts the at least one sidewall and the bottom surface of the at least one opening.

8. The apparatus of claim 7, wherein the at least one boiling enhancement material layer contacts with at least one sidewall and the bottom surface of the at least one opening without contacting the second surface of the heat dissipation device.

9. The apparatus of claim 6, wherein the at least one surface area enhancement structure comprises at least one opening extending through the heat dissipation device from the first surface to the second surface thereof.

10. An apparatus, comprising:
an integrated circuit device having a first surface and an opposing second surface;
a heat dissipation device having a first surface and an opposing second surface, wherein the first surface of the heat dissipation device is thermally attached to the second surface of the integrated circuit device and wherein the heat dissipation device includes at least one surface area enhancement structure formed therein and/or thereon; and
at least one boiling enhancement material layer on at least a portion of the at least one surface area enhancement structure of the heat dissipation device.

11. The apparatus of claim 10, wherein the at least one surface area enhancement structure comprises at least one projection extending from the second surface of the heat dissipation device.

12. The apparatus of claim 11, wherein the at least one projection is defined by at least one sidewall and a top surface.

13. The apparatus of claim 12, wherein the at least one boiling enhancement material layer contacts the at least one sidewall of the at least one projection without contacting the top surface of the at least one projection.

14. The apparatus of claim 13, wherein the at least one boiling enhancement material layer contacts the second surface of the heat dissipation device.

15. The apparatus of claim 10, wherein the at least one surface area enhancement structure comprises at least one opening extending into the heat dissipation device from the second surface thereof.

16. The apparatus of claim 15, wherein the at least one opening is defined by at least one sidewall and a bottom surface, and wherein the at least one boiling enhancement material layer contacts the at least one sidewall and the bottom surface of the at least one opening.

17. The apparatus of claim 16, wherein the at least one boiling enhancement material layer contacts with at least one sidewall and the bottom surface of the at least one opening without contacting the second surface of the heat dissipation device.

18. The apparatus of claim 15, wherein the at least one surface area enhancement structure comprises at least one opening extending through the heat dissipation device from the first surface to the second surface thereof.

19. A system, comprising:
an electronic board; and
an integrated circuit package electrically attached to the electronic board, wherein the integrated circuit package comprises:
an integrated circuit device having a first surface and an opposing second surface;
a heat dissipation device having a first surface and an opposing second surface, wherein the first surface of the heat dissipation device is thermally attached to the second surface of the integrated circuit device and wherein the heat dissipation device includes at least one surface area enhancement structure formed therein and/or thereon; and
at least one boiling enhancement material layer on at least a portion of the at least one surface area enhancement structure of the heat dissipation device.

20. The system of claim 19, wherein the at least one surface area enhancement structure comprises at least one projection extending from the second surface of the heat dissipation device.

21. The system of claim 20, wherein the at least one projection is defined by at least one sidewall and a top surface.

22. The system of claim 21, wherein the at least one boiling enhancement material layer contacts the at least one sidewall of the at least one projection without contacting the top surface of the at least one projection.

23. The system of claim 19, wherein the at least one surface area enhancement structure comprises at least one opening extending into the heat dissipation device from the second surface thereof.

24. The system of claim 23, wherein the at least one opening is defined by at least one sidewall and a bottom surface, and wherein the at least one boiling enhancement material layer contacts the at least one sidewall and the bottom surface of the at least one opening.

25. The system of claim 23, wherein the at least one surface area enhancement structure comprises at least one opening extending through the heat dissipation device from the first surface to the second surface thereof.
